(19) United States
(12) Patent Application Publication
(10) Pub. No.: US 2004/0101981 A1
(43) Pub. Date: May 27, 2004

(54) Apparatus for repairing defect of substrate

(76) Inventor: Masahiko Morishita, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/415,346

(22) PCT Filed: Sep. 10, 2001
(86) PCT No.: PCT/JP01/07852

(51) Int. Cl. H01L 21/00

(52) U.S. Cl. 438/5; 219/444.1

(57) ABSTRACT

The present invention relates to a substrate defect repairing device which repairs defects of a substrate such as a wafer and a liquid crystal substrate. More particularly, an object of the present invention is to provide a substrate defect repairing device which can effectively prevent defects occurring in a substrate such as a wafer from deteriorating.

In order to achieve the above-mentioned object, after a Si wafer 1 has been mounted on a wafer positioning base 4, a personal computer 9 recognizes a position of a chipping on the basis of an image signal derived from an image picked up by a position detection sensor 5. The personal computer 9 rotates the Si wafer 1 mounted on the wafer positioning base 4, and stops the position at a position where a laser light beam 8 from a laser oscillator 7 can be applied to a chipping 6, thereby completing a positioning process. Then, a laser light beam 8 is applied to the chipping 6 from the laser oscillator 7 so that the chipping 6 and the peripheral portion thereof are melted to repair the chipping 6.

### TECHNICAL FIELD

The present invention relates to a substrate defect repairing device which repairs defects of a substrate such as a wafer and a liquid crystal substrate in a manufacturing process of a semiconductor device, a liquid crystal device and the like.

### BACKGROUND ART

FIGS. 22 and 23 are explanatory diagrams showing a defective state of a wafer. As shown in these figures, a wafer 25 sometimes has a defect such as a chipping 6 or a crack 16. These defects tend to occur due to a trouble in a manufacturing device of a semiconductor or the like which carries out a process on the wafer 25 or a mishandling or the like of the operator who handles the wafer 25.

Conventionally, when such a defect is negligible, the corresponding manufacturing process, as it is, is continued, while when the degree of the defect of the wafer 25 is serious as shown in FIG. 23, the wafer is omitted (disposed). In other words, in the case when, on the assumption that a defect of a wafer 25 shown in FIG. 22 is negligible, the corresponding manufacturing process is continued, a big crack 16b might occur beginning from a chipping 6 or a crack 16 as shown in FIG. 23 due to a mechanical impact, a thermal impact or the like exerted on a chipping tip portion 6a, a peripheral portion of the chipping 6b or the crack 16, resulting in a serious defect such as a cracked wafer 25; and in the event of such a serious defect, the wafer 25 is omitted.

Moreover, in the case of a wafer having a large diameter (for example, 5 to 12 inches in the case of Si), a thin-film wafer (approximately, 100 to 700 μm) or an epiwafer (epitaxial wafer) that has a difficulty in controlling a wafer edge shape, defects such as a chipping 6 and a crack 16 are more likely to occur. Furthermore, since the epiwafer is expensive, omitting this causes a serious loss in costs.

As described above, in the problem with the conventional technique, once a defect occurs in a wafer during a manufacturing process, this is developed to a serious defect during a manufacturing process, and omitting such a wafer causes degradation in the yield of the product.

Moreover, when a serious defect occurs in a wafer and the wafer is damaged, extra costs and time are required for cleaning process or the like of the foreign matters caused by the damage of the wafer, resulting in serious losses in costs and time and also prolonged manufacturing process time.

### DISCLOSURE OF THE INVENTION

An object of the present invention is to solve the above-mentioned problems, and to provide a substrate defect repairing device which can effectively prevent a defect occurring in a substrate such as a wafer from deteriorating.

A first aspect of a semiconductor device according to the present invention includes: substrate mounting means for mounting a substrate to be processed; defect detecting means for detecting the presence or absence of a defect in the substrate to be processed, and obtaining information for defect detection including a defect position, upon detection of the defect; and defect repairing means for repairing the defect by melting the defect portion and the peripheral area of the substrate to be processed on the basis of the information for defect detection.

In a second aspect of a semiconductor device according to the present invention, the defect repairing means includes: local melting means for locally melting the substrate to be processed; and melt-positioning means for carrying out a positioning process so as to allow the local melting means to melt the defect portion and the peripheral area thereof on the basis of the information for defect detection.

In a third aspect of a semiconductor device according to the present invention, the local melting means includes a laser oscillator for locally applying a laser beam onto the substrate to be processed so as to melt the corresponding portion.

In a fourth aspect of a semiconductor device according to the present invention, the local melting means includes local heating means for locally heating the substrate to be processed.

In a fifth aspect of a semiconductor device according to the present invention, the local heating means includes a plurality of partial heating units which can be individually set in the lighting and lighting-out processes thereof.

In a sixth aspect of a semiconductor device according to the present invention, the local melting means includes fixed local melting means which is secured to a predetermined position, the substrate mounting means includes movable substrate mounting means capable of carrying out a shifting operation for shifting the substrate to be processed so as to change the portion to be melted by the local melting means, and the melt-positioning means includes control means controlling said shifting operation carried out by the substrate mounting means on the basis of the information defect detection.

In a seventh aspect of a semiconductor device according to the present invention, the substrate to be processed includes a disc-shaped substrate in its plane shape, and the shifting operation by the movable substrate mounting means includes a rotative operation rotating the substrate to be processed at a substantially center position of the substrate to be processed as a center.

In an eighth aspect of a semiconductor device according to the present invention, the shifting operation by the movable substrate mounting means includes an operation shifting the substrate to be processed so that the meltable portion by the local melting means is changed within a predetermined shifting area in the substrate to be processed.

In a ninth aspect of a semiconductor device according to the present invention, the local melting means includes movable local melting means carrying out a shifting operation to shift itself so that the meltable portion by the local melting means is changed within a predetermined shifting area in the substrate to be processed, and the melt-positioning means includes control means controlling the shifting operation by the movable local melting means on the basis of the information for defect detection.

In a tenth aspect of a semiconductor device according to the present invention, the substrate to be processed has first and second main surfaces, the substrate mounting means includes substrate mounting means for two-directional melting mounting the substrate to be processed in a manner so as to be subjected to a melting process from the respective sides of the first and second main surfaces, and the local melting means includes first local melting means carrying out a melting process on the substrate to be processed from the first main surface side, and second local melting means carrying out a melting process on the substrate to be processed from the second main surface side.

In an eleventh aspect of a semiconductor device according to the present invention, the first and second local melting means includes first and second laser oscillators locally applying laser beams on the first and second main surface sides of the substrate to be processed so as to carry out the melting processes.

In a twelfth aspect of a semiconductor device according to the present invention, the first and second local melting means includes first and second local heating means locally heating the substrate to be processed from the first and second main surface sides, respectively.

In a thirteenth aspect of a semiconductor device according to the present invention, the first local melting means includes a laser oscillator locally applying a laser beam to the substrate to be processed from the first main surface side so as to carry out a melting process, and the second local melting means includes local heating means locally heating the substrate to be processed from the second main surface side.

A fourteenth aspect of a semiconductor device according to the present invention is further includes: a substrate housing unit for housing a plurality of substrates; and transporting means capable of carrying out a first transporting process which takes one substrate out of the plurality of substrates in the substrate housing unit as the substrate to be processed and transports and mounts the substrate to be processed on the substrate mounting means, and a second transporting process which detaches the substrate to be processed from the substrate mounting means and transports and houses the substrate to be processed in the substrate housing unit.

A fifteenth aspect of a semiconductor device according to the present invention is further includes: control means for controlling the first and second transporting processes of the transporting means.

In a sixteenth aspect of a semiconductor device according to the present invention, the substrate to be processed includes a Si wafer, a GaAs substrate or a glass substrate for liquid crystal.

In a seventeenth aspect of a semiconductor device according to the present invention, the defect detecting means has a recording function of recording analysis information including at least information indicative of the defect position in the substrate to be processed.

In an eighteenth aspect of a semiconductor device according to the present invention, the defect includes a chipping or a crack.

According to the first aspect of a substrate defect repairing device of the present invention, the defect repairing means melts a defect portion and the peripheral area thereof to repair the defect, so that it becomes possible to effectively prevent the defect of the substrate to be processed from deteriorating.

According to the second aspect of a substrate defect repairing device of the present invention, the melt positioning means carries out a positioning process so as to allow the local melting means to melt a defect portion and the peripheral area thereof to repair the defect, so that it becomes possible to obtain high defect repairing precision.

According to the third aspect of a substrate defect repairing device of the present invention, the laser oscillator applies a laser beam, so that it becomes possible to melt a defect portion and the peripheral area thereof with high positional precision.

According to the fourth aspect of a substrate defect repairing device of the present invention, the local heating means carries out a local heating process, so that it becomes possible to melt a defect portion and the peripheral area of the substrate to be processed, with a comparatively large range.

According to the fifth aspect of a substrate defect repairing device of the present invention, a plurality of partial heating units are selectively lighted on, so that it becomes possible to heat an area suitable for a defect shape of the substrate to be processed.

According to the sixth aspect of a substrate defect repairing device of the present invention, the movable substrate mounting means is allowed to execute the shifting operation for shifting the substrate to be processed under control of the control means, so that it becomes possible to expand a defect repairing area of the substrate to be processed.

According to the seventh aspect of a substrate defect repairing device of the present invention, the above-mentioned meltable portion is altered in the rotation direction on the substrate to be processed by rotating the substrate to be processed. Therefore, for example, a repairing process for chipping or the like occurring along the outer circumference of the substrate to be processed can be carried out uniformly.

According to the eighth aspect of a substrate defect repairing device of the present invention, defects within a predetermined shifting area in the substrate to be processed can be repaired by the shifting operation of the movable substrate mounting means. For example, when the predetermined shifting area is set to the same area as the entire area of the substrate to be processed, it becomes possible to repair defects of the entire area of the substrate to be processed.

According to the ninth aspect of a substrate defect repairing device of the present invention, the shifting operation of the movable local melting means itself can repair defects within a predetermined shifting area in the substrate to be processes. For example, when the predetermined shifting area is set to the same area as the entire area of the substrate to be processed, it becomes possible to repair defects of the entire area of the substrate to be processed.

According to the tenth aspect of a substrate defect repairing device of the present invention, the first and second local melting means make it possible to melt the substrate to be processed from both of the first and second main surfaces, so that it becomes possible to appropriately repair even a defect generated from the first main surface to the second main surface of the substrate to be processed.

According to the eleventh aspect of a substrate defect repairing device of the present invention, the first and second laser oscillators apply laser beams to a defect portion of a substrate to be processed and the peripheral area thereof from both of the first and second main surfaces, so that it becomes possible to carry out a melting process with high positional precision.

According to the twelfth aspect of a substrate defect repairing device of the present invention, the local heating means carries out a local heating process from both of the first and second main surfaces, so that it becomes possible to melt a defect portion and the peripheral area thereof with a comparatively large range.

According to the thirteenth aspect of a substrate defect repairing device of the present invention, the laser beam applied from the laser oscillator makes it possible to melt a defect portion of a substrate to be processed and the peripheral area thereof from the first main surface side with high positional precision, and the local heating means carries out a local heating process on the defect portion of the substrate to be processed and the peripheral area thereof from the second main surface side, so that it becomes possible to melt the defect portion and the peripheral area thereof with a comparatively large range.

According to the fourteenth aspect of a substrate defect repairing device of the present invention, the transporting means carries out the first and second transporting processes, so that a plurality of substrates housed in the substrate housing unit can be repaired as the substrates to be processed, respectively, and the second transporting process makes it possible to house the substrate to be processed that has been subjected to the defect repairing processes in the substrate housing unit; thus, the substrate mounting and removing operations can be carried out automatically.

According to the fifteenth aspect of a substrate defect repairing device of the present invention, the first and second transporting processes are carried out under control of the control means; thus, in the case where a substrate having a defect has been preliminarily recognized, only the substrate having a defect is selected from a plurality of substrates as a substrate to be processed and subjected to a defect repairing process, and in the case where a substrate having a defect has not been recognized, after all the substrates have been mounted onto the substrate mounting means as substrates to be processed, substrates from which no defects have been found by the defect detecting means are readily returned to the substrate housing unit so that it is possible to carry out a defect repairing process on a plurality of substrates effectively.

According to the sixteenth aspect of a substrate defect repairing device of the present invention, it is possible to carry out a defect repairing process on a Si wafer, a GaAs substrate or a glass substrate for liquid crystal.

According to the seventeenth aspect of a substrate defect repairing device of the present invention, analysis information which includes at least information indicating a defect position in a substrate to be processed is recorded so that, on the basis of the above-mentioned analysis information after predetermined manufacturing processes using a number of substrates as samples, it is possible to obtain a defect distribution in a plurality of substrates, and consequently to carry out a detailed defect analysis by using the above-mentioned defect distribution.

According to the eighteenth aspect of a substrate defect repairing device of the present invention, it becomes possible to repair chippings or cracks generated in the substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an explanatory diagram showing a structure of a wafer crack prevention device according to embodiment 1;

FIG. 2 is an explanatory diagram showing a detailed structure of a wafer transporting arm of FIG. 1;

FIG. 3 is an explanatory diagram showing a detailed structure of a wafer transporting arm of FIG. 1;

FIG. 4 is an explanatory diagram showing a chipping state of a Si wafer prior to a repairing process;

FIG. 5 is an explanatory diagram showing a chipping state of a Si wafer after the repairing process;

FIG. 6 is an explanatory diagram showing a structure of a wafer crack prevention device according to embodiment 2;

FIG. 7 is an explanatory diagram showing a local heater of a wafer crack prevention device according to embodiment 3;

FIG. 8 is a plan view showing a detailed structure of a local heater;

FIG. 9 is an explanatory diagram showing a heating state prepared by a partial local heater;

FIG. 10 is an explanatory diagram showing a monitor screen in a wafer crack prevention device according to embodiment 4;

FIG. 11 is an explanatory diagram showing a Si wafer selection function from a wafer cassette according to embodiment 4;

FIG. 12 is an explanatory diagram schematically showing a defect analysis example obtained by utilizing the wafer crack prevention device according to embodiment 5;

FIG. 13 is an explanatory diagram showing a movable laser oscillator and the periphery thereof in the wafer crack prevention device according to embodiment 6;

FIG. 14 is an explanatory diagram showing a movable local heater and the periphery thereof in the wafer crack prevention device according to embodiment 7;

FIG. 15 is an explanatory diagram showing a movable wafer positioning base and the periphery thereof in the wafer crack prevention device according to embodiment 8;

FIG. 16 is an explanatory diagram showing a movable wafer positioning base and the periphery thereof in the wafer crack prevention device according to embodiment 8;

FIG. 17 is an explanatory diagram showing a movable wafer positioning base and the periphery thereof in the wafer crack prevention device according to embodiment 9;

FIG. 18 is an explanatory diagram showing a movable wafer positioning base and the periphery thereof in the wafer crack prevention device according to embodiment 9;

FIG. 19 is an explanatory diagram showing one portion of a structure of a wafer crack prevention device according to embodiment 10;

FIG. 20 is an explanatory diagram showing one portion of a structure of a wafer crack prevention device according to embodiment 11;

FIG. 21 is an explanatory diagram showing one portion of a structure of a wafer crack prevention device according to embodiment 12;

FIG. 22 is an explanatory diagram showing an example of comparatively slight chipping and crack in a Si wafer; and

FIG. 23 is an explanatory diagram showing an example of serious chipping and crack in a Si wafer.

### BEST MODES FOR CARRYING OUT THE INVENTION

### 1. Embodiment 1

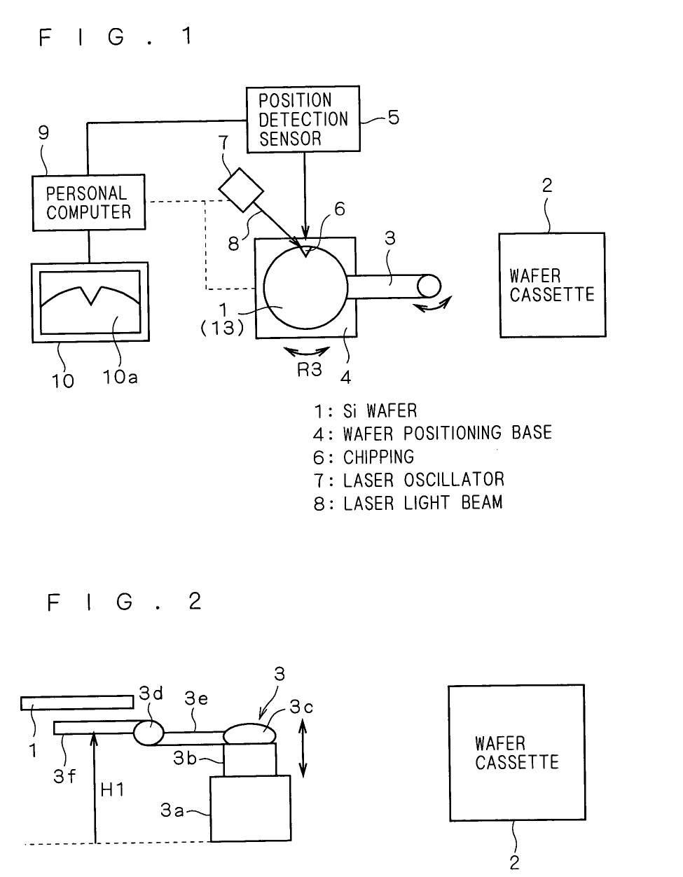

FIG. 1 is an explanatory diagram showing the entire structure of a wafer crack prevention device (substrate defect repairing device) according to embodiment 1 of the present invention. Embodiment 1 shows a wafer crack prevention device which is mainly used for a repairing process for chipping. As shown in FIG. 1, a disc-shaped Si wafer 1, housed in a wafer cassette 2 serving as a substrate housing unit, is used as a substrate to be processed, and this may be mounted on a wafer positioning base 4 by a wafer transporting arm 3.

FIG. 2 is an explanatory diagram showing the wafer transporting arm 3 serving as transporting means in detail. As shown in these figures, the wafer transporting arm is constituted by a supporting portion 3a, a longitudinal extending unit 3b, first and second rotation shafts 3c, 3d and first and second arm portions 3e, 3f.

The longitudinal extending unit 3b is provided on the supporting portion 3a so as to be freely extended longitudinally, and the height H1 of the second arm portion 3f is set to a height of a Si wafer 1 and a height of a wafer positioning base 4 (not shown) in a wafer cassette 2 by the extension and shrinkage of the longitudinal extending unit 3b.

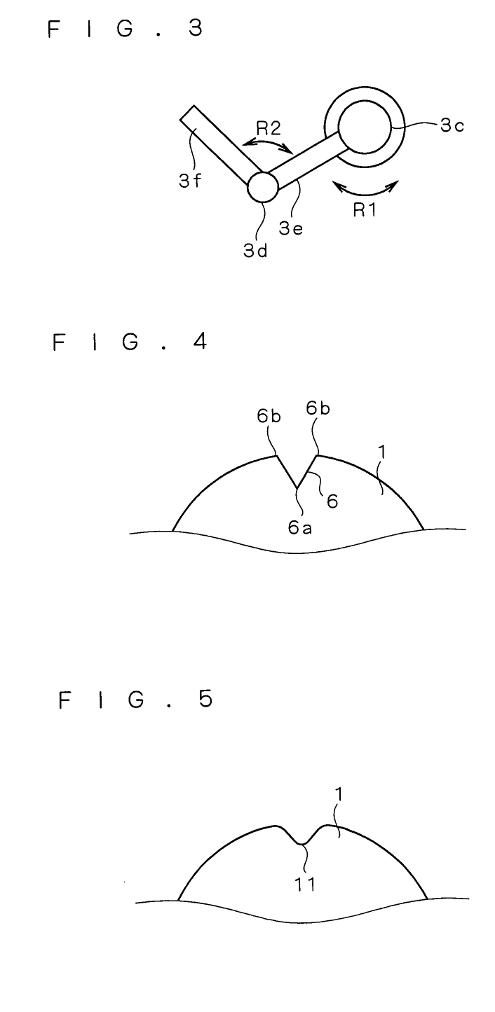

FIG. 3 is an explanatory diagram showing a rotation mechanism of the wafer transporting arm 3. As shown in this figure, a first rotation shaft 3c is provided on the longitudinal extending unit 3b, and the first arm portion 3e is provided so as to make a rotation R1 centered on the first rotation shaft 3c, and a second rotation shaft 3d is attached to the tip of the first arm portion 3e, and the second arm portion 3f is provided so as to make a rotation R2 centered on the second rotation shaft 3d.

The wafer transporting arm 3 having such a structure takes a plurality of Si wafers 1 from a wafer cassette 2 that houses these wafers by utilizing the extending mechanism of the longitudinal extending unit 3b and the rotation mechanisms of the first arm portions 3e, 3f, and these are transported and mounted (loading) on the wafer positioning base 4 with high precision; thus, it is capable of carrying out the first transporting process. Moreover, the wafer transporting arm 3 removes the Si wafer 1 mounted on the wafer positioning base 4, and transports and returns it to the wafer cassette 2; thus, it is also capable of carrying out the second transporting process.

In other words, the wafer transporting arm 3 carries out the first and second transporting processes so that the Si wafer 1 is automatically mounted onto the wafer positioning base 4 and also removed from the wafer positioning base 4.

As shown in the aforementioned FIG. 1, the wafer positioning base 4, which serves as a substrate bearing means, can rotate in the rotation direction of R3 centered on the center portion of the Si wafer 1 mounted thereon, under the control of a personal computer 9. Here, the rotation of the wafer positioning base 4 is carried out under the control of the personal computer 9.

A position detection sensor 5 obtains an image signal derived from the entire image of the Si wafer 1 as information for defect detection, and gives this signal to the personal computer 9. On the basis of gradations and shapes in the image specified by the image signal, the personal computer 9 recognizes coordinates (defect portion) of a defect, such as a chipping and a crack, on the Si wafer 1, and stores the coordinates in a storing unit, not shown. Moreover, on the basis of the image signal, the personal computer 9 also makes it possible to display the image of the Si wafer 1 on the monitor screen 10a of the monitor 10.

A laser oscillator 7, which serves as local melting means for the wafer, is secured to the ground in a manner so as to apply a laser beam 8 to a predetermined meltable portion on the periphery of the Si wafer 1, and allowed to apply the laser beam 8 under the control of the personal computer 9.

In this arrangement, after the Si wafer 1 has been mounted on the wafer positioning base 4, the personal computer 9 recognizes the position of a chipping on the basis of the image signal derived from an image that has been picked up by the position detection sensor 5. In this case, when no defect such as a chipping has been detected, the process is completed.

When a defect on the Si wafer 1 is detected, the process is continued, and the personal computer 9 rotates the Si wafer 1 mounted on the wafer positioning base 4 in the rotation direction of R3 so that the rotation is stopped at a position where the laser light beam 8 is applicable to the chipping 6, thereby completing the positioning process.

Thereafter, the laser oscillator 7 applies the laser light beam 8 onto the chipping 6. As a result, the chipping 6 and the peripheral area thereof are melted, and repaired. Here, with respect to the laser light beam 8, the apparent quantity of current is finely adjusted by turning the power supply of the laser oscillator 7 on and off by using an inverter or the like so that the laser light beam 8 is set so as to have characteristics suitable for the degree of a defect such as a chipping 6. The laser light beam 8 is particularly effective to repair a chipping 6, a crack or the like having a comparatively small size.

FIG. 4 is an explanatory diagram showing a chipping prior to a repairing process by a wafer crack prevention device. As shown in this figure, the chipping 6 is generated as a loss portion of the Si wafer 1 appearing from the tip of a chipping 6a to the chipping peripheral portion 6b, on the periphery of the Si wafer 1.

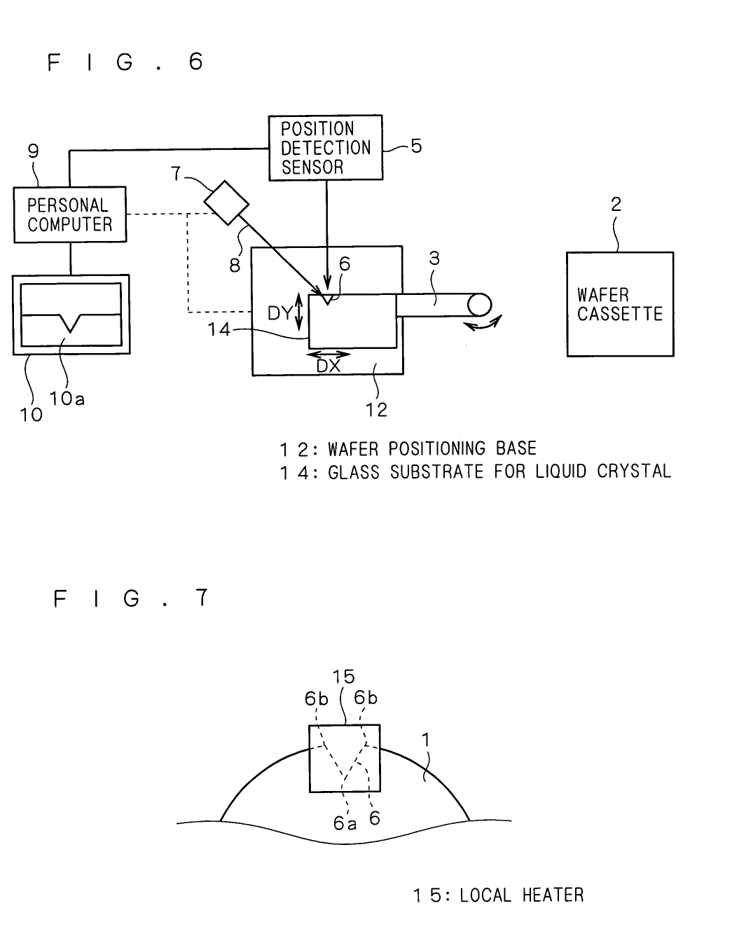

FIG. 5 is an explanatory diagram showing a chipping that has been repaired by the wafer crack prevention device. As shown in this figure, the tip 6a of a chipping 6 and the chipping peripheral portion 6b are melted by the irradiation of the laser light beam 8 to be deformed into a smooth shape; thus, the chipping 11 is repaired.

The Si wafer 1 having such a repaired chipping 11 is housed in the wafer cassette 2 through the second transporting process carried out by the above-mentioned wafer transporting arm 3.

In this manner, the wafer crack prevention device of embodiment 1 makes the shape of a chipping smoother through the irradiation of the laser light beam 8 from the laser oscillator 7; therefore, it becomes possible to positively prevent cracks from occurring in the tip 6a of a chipping and the chipping peripheral portion 6b, to prevent the chipping shape from further developing, and also to positively prevent the defect from further deteriorating to cause a serious defect such as a wafer crack even when the manufacturing process of the wafer is further continued.

### 2. Embodiment 2

In a wafer crack prevention device according to embodiment 2, in place of the Si wafer 1 of embodiment 1, a GaAs substrate 13 or a glass substrate 14 for liquid crystal is used as a subject of the process. In the case of the GaAs substrate 13, except that the Si wafer 1 is replaced by the GaAs substrate 13, the structure of the wafer crack prevention device and the operations thereof are the same as those shown in embodiment 1 by reference to FIG. 1.

FIG. 6 is an explanatory diagram showing the entire structure of a wafer crack prevention device according to embodiment 2 of the present invention. In comparison with the entire structure of the device shown in embodiment 1 of shown in FIG. 1, embodiment 2 is different from embodiment 1 in that a rectangular glass substrate 14 for liquid crystal is used as a subject in place of a round Si wafer 1, and in that, in embodiment 2, a wafer positioning base 12, which can shift a mounted liquid crystal glass substrate 14 in the X-direction DX and Y-direction DY, is applied in place of the wafer positioning base 4. In other words, the wafer positioning base 12 makes it possible to shift the glass substrate 14 for liquid crystal in the X-direction DX and the Y-direction DY so that the irradiation position of the laser light beam 8 applied by the laser oscillator 7 is varied within the entire area on the glass substrate 14 for liquid crystal. Here, the other structures are the same as those shown in FIG. 1; therefore, the description thereof is omitted.

In this arrangement, after a glass substrate 14 for liquid crystal has been mounted on the wafer positioning base 12, the personal computer 9 recognizes the position of a chipping on the basis of the image signal derived from an image that has been picked up by the position detection sensor 5. In this case, when no defect such as a chipping has been detected, the process is completed.

Here, the mounting process of the glass substrate 14 for liquid crystal onto the wafer positioning base 12 is carried out by operating the wafer transporting arm 3 in the same manner as the mounting process of the Si wafer 1 onto the wafer positioning base 4 in embodiment 1.

When a defect on the Si wafer 1 is detected, the process is continued, and the personal computer 9 shifts the glass substrate 14 for liquid crystal mounted on the wafer positioning base 12 in the X-direction DX and Y-direction DY, that is, two-dimensionally, so that the two-dimensional shift is stopped at a position where the laser light beam 8 from the laser oscillator 7 is applicable to the chipping 6, thereby completing the positioning process.

Thereafter, the laser oscillator 7 applies the laser light beam 8 onto the laser oscillator 7. As a result, the chipping 6 is repaired.

In this manner, embodiment 2 shown in FIG. 6 has an arrangement in which, with respect to the rectangular glass substrate 14 for liquid crystal, a laser light beam 8 is applied to a chipping 6 that is generated on the peripheral portion thereof; therefore, by using the wafer positioning base 12 that can shift the glass substrate 14 for liquid crystal that has been mounted thereon in the X-direction DX and the Y-direction DY, it becomes possible to provide the same effects as embodiment 1.

### 3. Embodiment 3

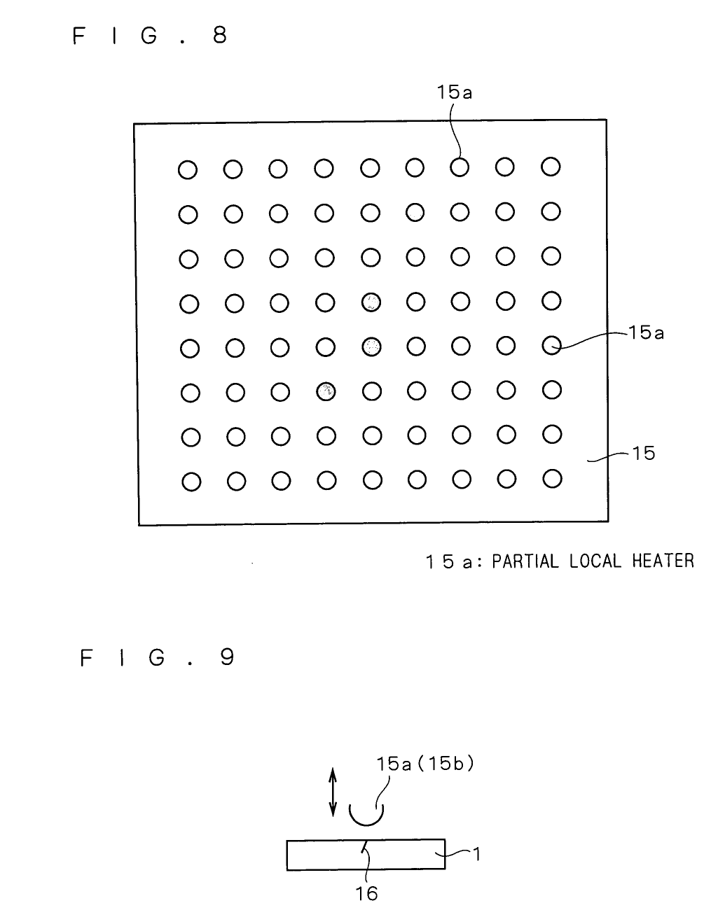

FIG. 7 is an explanatory diagram showing a local heater module of a wafer crack prevention device according to embodiment 3 of the present invention. As shown in this figure, in place of the laser oscillator 7, a local heater 15 is used as wafer melting means. Here, the other structure is the same as that of the entire structure of embodiment 1 shown in FIG. 1.

FIG. 8 is a plan view showing the structure of the local heater. As shown in this figure, a plurality of partial local heaters 15a are provided in the local heater 15 in a matrix format, and these partial local heaters 15a are respectively set to a light-on state or a light-out state. In an example shown in FIG. 8, hatched portions indicate partial local heaters 15a that are in the light-on state, and the partial local heaters 15a can be selectively lighted on, for example, in accordance with the shape of a crack. The local heater 15 is particularly effective to repair a chipping 6 or a crack 16 that is comparatively long.

FIG. 9 is an explanatory diagram showing a positional relationship between partial local heaters 15a and a Si wafer 1. As shown in FIG. 9, the partial local heaters 15a are provided closely to a crack 16 on the Si wafer 1, and by turning the power supply to be applied to the partial local heaters 15a on and off by using an inverter or the like, the temperature of the partial local heaters 15a is controlled; thus, the crack 16 in the Si wafer 1 and the peripheral area thereof are melted so that the portions separated by the crack 16 are joined to each other to repair the crack 16.

In this arrangement, in the same manner as embodiment 1, after the Si wafer 1 has been mounted onto the wafer positioning base 4, the personal computer 9 recognizes the position of a chipping on the basis of the image signal derived from an image that has been picked up by the position detection sensor 5. In this case, when no defect such as a chipping has been detected, the process is completed.

When a defect on the Si wafer 1 is detected, the process is continued, and the personal computer 9 rotates the Si wafer 1 mounted on the wafer positioning base 4 in the rotation direction of R3 so that the rotation is stopped at a position where the local heater 15 can heat and melt the crack 16, thereby completing the positioning process.

Thereafter, the local heater 15 is allowed to heat and melt the loss portion of the Si wafer 1 so that the defect such as a crack 16 is repaired.

In this manner, the wafer crack prevention device of embodiment 3 makes the shape of a chipping smoother through the heating and melting processes given by the local heater 15, or melts and joins the cracked portions to each other; therefore, it becomes possible to positively prevent cracks from occurring in the chipping tip portion 6a and the chipping peripheral portion 6b, to prevent the chipping shape from further developing as well as the cracks from increasing, and also to positively prevent the defect from further deteriorating to cause a serious defect such as a wafer crack even when the manufacturing process of the wafer is further continued.

### 4. Embodiment 4

In the case when among a plurality of Si wafers 1 housed in the wafer cassette 2, a Si wafer 1 having a defect such as a chipping 6 and a crack 16 has already been recognized, only the Si wafer 1 having a defect can be subjected to a defect repairing process.

The wafer crack prevention device according to embodiment 4 features that it has a selection function from a plurality of Si wafers 1 housed in the wafer cassette 2. Here, the entire structure thereof is the same as that shown in embodiment 1 by reference to FIG. 1, and the operations thereof are the same as those shown in embodiment 1 except that a wafer selecting process, which will be described below, is added thereto.

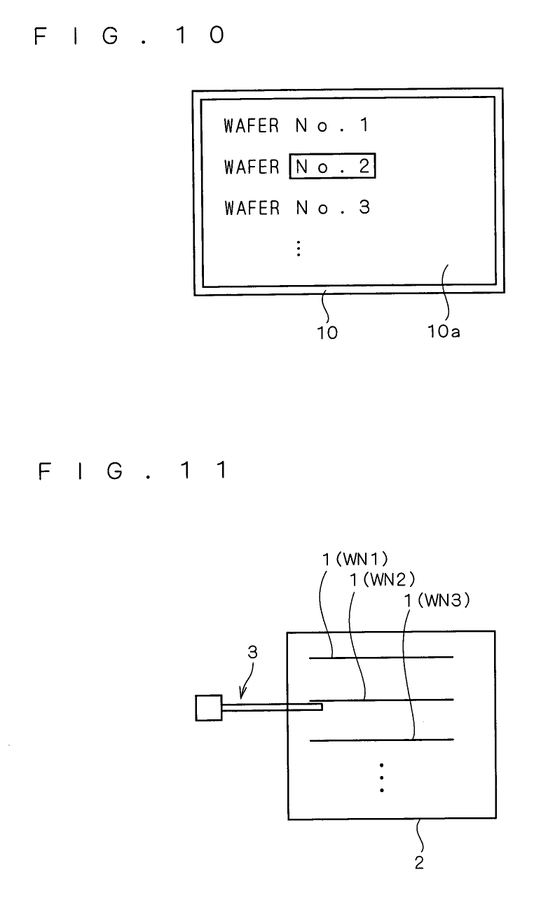

FIG. 10 is an explanatory diagram showing a wafer selection screen. FIG. 11 is an explanatory diagram showing a housed state of Si wafers 1 inside the wafer cassette 2. As shown in FIG. 11, a plurality of Si wafers 1 are housed successively in the order of WN1, WN2, WN3, and these wafers correspond to wafers No. 1, No. 2, No. 3 that are shown in a monitor screen 10a in FIG. 10.

Therefore, the Si wafers 1 housed in the wafer cassette 2 are selectable by using the wafer numbers; and, for example, when it has been preliminarily determined that there is a defect in wafer 1 of No. 2 (WN2), the wafer of No. 2 is selected from the monitor screen 10a shown in FIG. 10 so that the Si wafer 1 (WN2) can be mounted on the wafer positioning base 4 by driving the wafer transporting arm 3 under the control of the personal computer 9.

In this manner, in accordance with the wafer crack prevention device of embodiment 4, a plurality of Si wafers 1 housed in the wafer cassette 2 are selectively mounted on the wafer positioning base 4 so that, when it has been preliminarily determined which wafer has a defect among the Si wafers 1 housed in the wafer cassette 2, only the Si wafer 1 having a defect can be repaired; thus, it is possible to carry out the repairing process effectively.

Here, in the case when it has not been preliminarily determined which wafer has a defect among the Si wafers 1 housed in the wafer cassette 2, all the Si wafers 1 housed in the wafer cassette 2 are successively mounted on the wafer positioning base 4 so that the presence or absence of a defect is detected by the position detection sensor 5 and the personal computer 9.

Then, with respect to each Si wafer 1 from which a defect has been detected, the defect repairing process of the Si wafer 1 is carried out in the same manner as embodiment 1, and each Si wafer 1 from which no defect has been detected is readily returned to the wafer cassette 2.

### 5. Embodiment 5

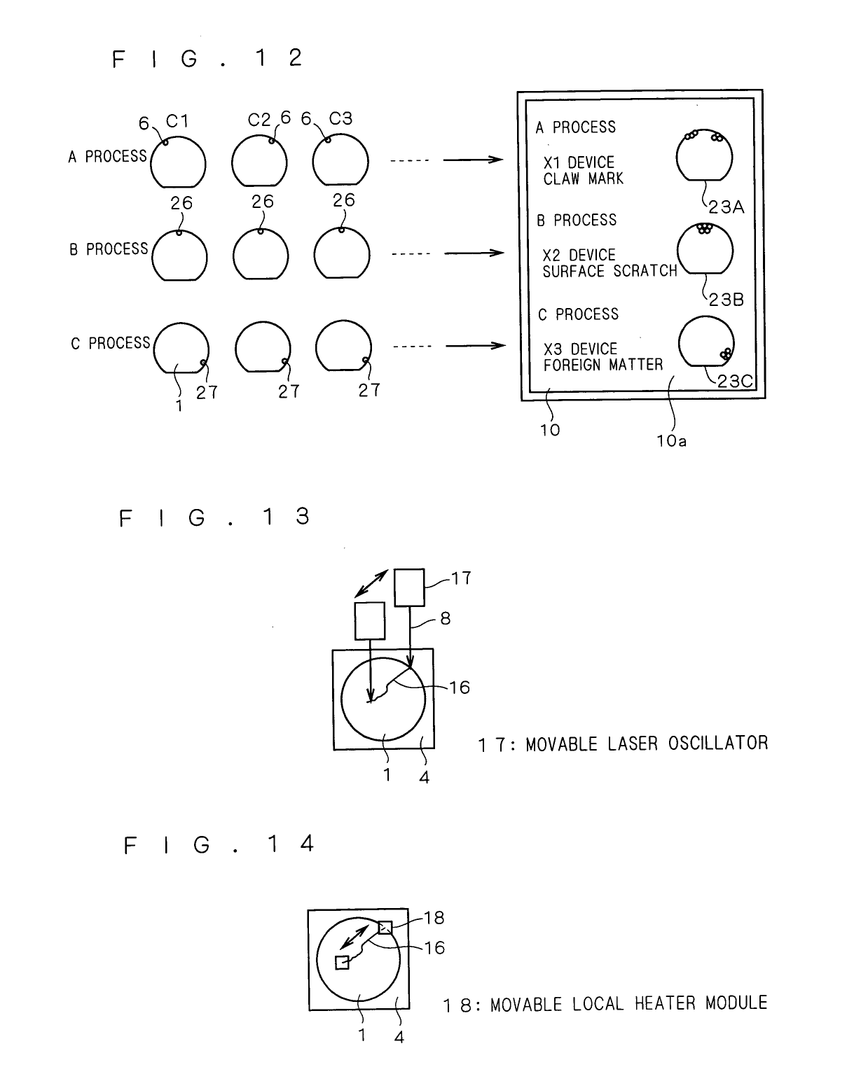

FIG. 12 is an explanatory diagram that schematically shows a recording function of a wafer crack prevention device according to embodiment 5. As shown in this figure, this recording function of analysis information includes a defect distribution wafer 23A that indicates a defect distribution on each Si wafer 1 of wafers C1, C2, C3, . . . that have been subjected to processes A, B and C. Here, the other structures thereof are the same as those of the wafer crack prevention device of embodiment 1 except for the above-mentioned recording function.

In addition to the above-mentioned defect distribution wafer, this recording function includes measurement pre-information such as the number of each lot housing a plurality of wafers, the position inside the lot, the name of a process, the name of a processing device that has carried out the process and a clamped position of the device (which is a position at which the device grabs a wafer, and might form a cause of chipping and crack generation). Additionally, the defect distribution wafer is obtained on the basis of measurement information including a chipping position, a chipping size, a crack position, a crack size, etc., with respect to each wafer after each of the processes is carried out, by using the wafer crack prevention device of embodiment 5.

The measurement pre-information and measurement information obtained by the recording function of the wafer crack prevention device of embodiment 5 are analyzed so that various defect analyses are carried out. For example, if, by collating the clamp position with the defect position on a defect portion wafer, it is found that the results of the collation are coincident with each other (show strong correlation), it is possible to analyze that the corresponding device causes the defect. Moreover, in the case when the kinds of wafers to be dealt with are different depending on lot numbers, the defect distribution wafers are compared with each other on a lot number basis so that characteristics of the wafers may be analyzed depending on the kinds of wafers. Moreover, in the case when defects other than the chipping 6 and the crack 16, such as surface scratches and foreign matters, can be detected by the position detection sensor 5 and the personal computer 9, a defect analysis may be carried out on the basis of a defect distribution wafer including these factors.

Examples shown in FIG. 12 show that the following analyses are available: on the basis of a wafer defect distribution 23A after the A process, it is analyzed that the generation position of a chipping 6 is coincident with a claw mark (clamp position) of the X1 device in the A process and that consequently, the X1 device has caused the generation of the defect; on the basis of the degree of generation of surface scratches 26 of a wafer defect distribution 23B after the B process, it is analyzed that the X2 device has generated the surface scratches; and on the basis of the degree of generation of foreign matters 27 shown in a wafer defect distribution in 23C, it is analyzed that the X3 device has generated the foreign matters.

Additionally, upon analysis, by taking it into consideration that there is an offset from an orientation flat position and a notch position, a function for correcting the rotation direction and the XY-direction of the wafer upon collating the wafer before and after the measurement may be prepared.

### 6. Embodiment 6

FIG. 13 is an explanatory diagram that schematically shows a movable laser oscillator of a wafer crack prevention device according to embodiment 6 of the present invention. As shown in this figure, this embodiment uses a movable laser oscillator 17 in place of the laser oscillator 7. The other structures thereof are the same as those of the entire structure of embodiment 1 shown by reference to FIG. 1.

As shown in the above-mentioned figure, the movable laser oscillator 17 is allowed to freely shift on the Si wafer 1. In other words, the movable laser oscillator 17 is capable of shifting itself so that the irradiation portion (meltable portion) of the laser light beam 8 from the movable laser oscillator 17 is varied over the entire area of the Si wafer 1.

Therefore, the laser light beam 8 is applied along a crack 16 several times while the movable laser oscillator 17 is being shifted along the crack 16 under the control of the personal computer 9 so that even in the case of a crack 16 having a comparatively large size that cannot be repaired by irradiation of the laser light beam 8 of one time, the entire crack 16 and the peripheral area thereof can be melted with high precision by applying the laser light beam 8 onto the entire portions evenly. Consequently, the crack 16 is joined and repaired with high precision.

In the above-mentioned embodiment 6, since the movable laser oscillator 17 is freely moved on the Si wafer 1, it is not necessary for the wafer positioning base 4 to have a rotation function. Moreover, in the present embodiment, for example, the crack 16 is repaired; however, the present embodiment is of course applied so as to repair a chipping 6.

### 7. Embodiment 7

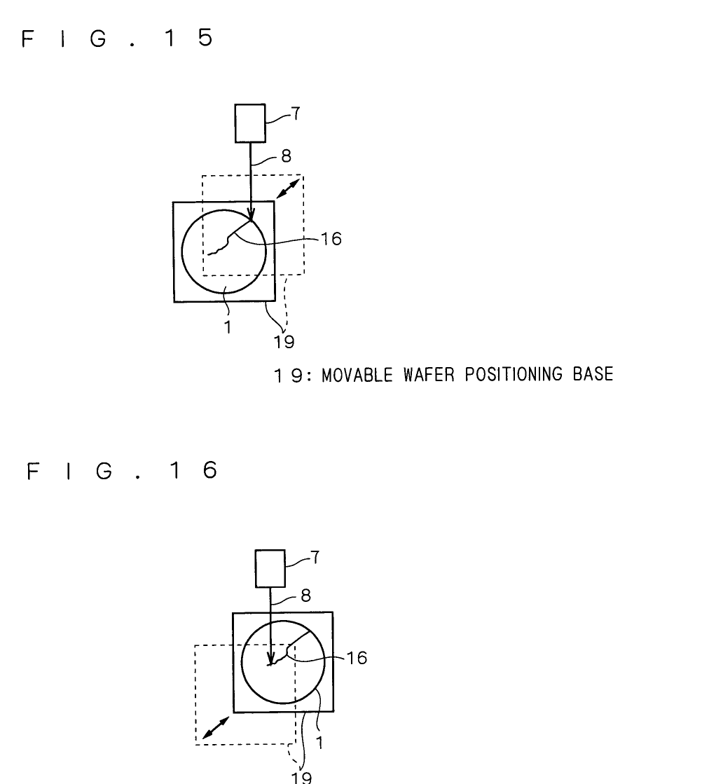

FIG. 14 is an explanatory diagram schematically showing a movable local heater of a wafer crack prevention device according to embodiment 7 of the present invention. As shown in this figure, this embodiment uses a movable local heater 18 in place of the laser oscillator 7. The other structures thereof are the same as those of the entire structure of embodiment 1 shown by reference to FIG. 1.

As shown in the above-mentioned figure, the movable local heater 18 is allowed to freely shift on the Si wafer 1. In other words, the movable local heater module 18 is capable of shifting itself so that the local heating process (meltable portion) by the movable local heater module 18 is varied over the entire area of the Si wafer 1.

Therefore, a plurality of heating and melting processes are carried out along a crack 16 while the movable local heater 18 is being shifted along the crack 16 under the control of the personal computer 9 so that even in the case of a crack 16 having a comparatively large size that cannot be repaired by heating and melting processes of one time, the entire crack 16 and the peripheral area thereof can be melted with high precision. Consequently, the crack 16 is joined and repaired with high precision.

In the above-mentioned embodiment 7, since the movable local heater 18 is freely moved on the Si wafer 1, it is not necessary for the wafer positioning base 4 to have a rotation function. Moreover, in the present embodiment, for example, the crack 16 is repaired; however, the present embodiment is of course applied so as to repair a chipping 6.

### 8. Embodiment 8

FIGS. 15 and 16 are explanatory diagrams that schematically show a movable wafer positioning base according to embodiment 8 of the present invention. As shown in this figure, this embodiment uses a movable wafer positioning base 19 in place of the wafer positioning base 4. The other structures thereof are the same as those of the entire structure of embodiment 1 shown by reference to FIG. 1.

As shown in these figures, the movable wafer positioning base 19 is allowed to freely shift so that the laser oscillator 7 of the Si wafer 1 mounted thereon for applying a laser light beam 8 has an irradiation area that can be set over the entire area of the Si wafer 1. Therefore, the laser light beam 8 is applied several times while the movable wafer positioning base 19 is being shifted so as to allow the laser light beam 8 to move along a crack 16 under the control of the personal computer 9; thus, even in the case of a crack 16 having a comparatively large size that cannot be repaired by irradiation of the laser light beam 8 of one time, the crack 16 is repaired with high precision in the same manner as embodiment 6.

Moreover, in the present embodiment, for example, the crack 16 is repaired; however, the present embodiment is of course applied so as to repair a chipping 6.

### 9. Embodiment 9

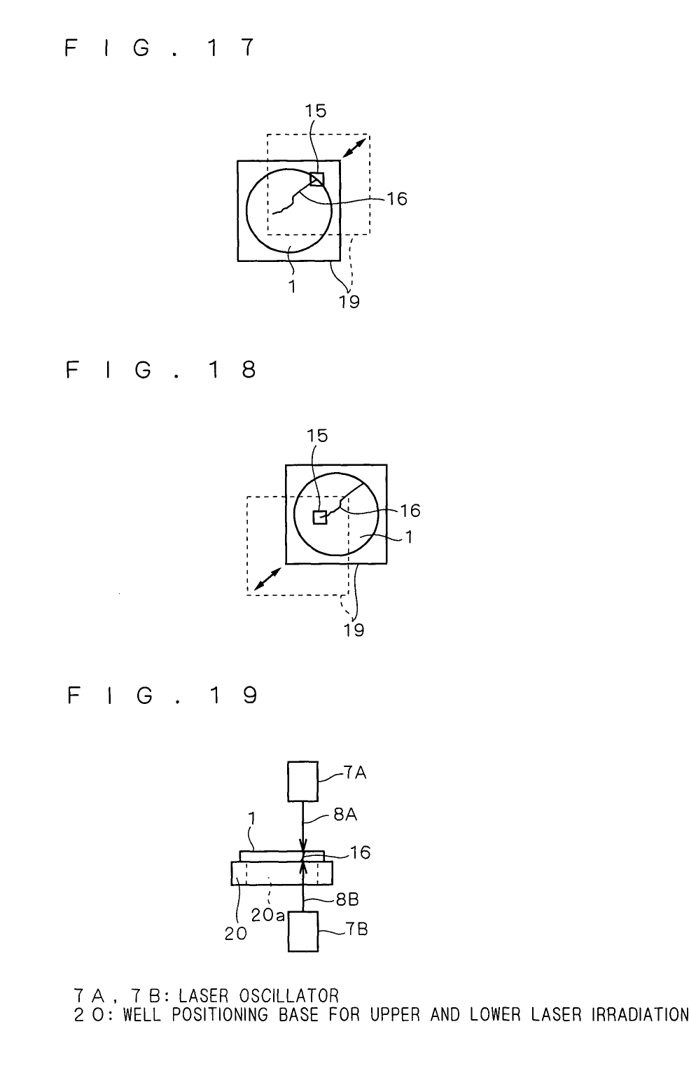

FIGS. 17 and 18 are explanatory diagrams that schematically show a movable wafer positioning base of a wafer crack prevention device according to embodiment 9 of the present invention. As shown in these figures, in place of the laser oscillator 7, a local heater 15 is used as wafer melting means, and a movable positioning base 19 is used in place of the wafer positioning base 4. Here, the other structure is the same as that of the entire structure of embodiment 1 shown in FIG. 1.

As shown in these figures, the movable wafer positioning base 19 is allowed to freely shift on the Si wafer 1 so that the heating area of the local heater 15 provided on the Si wafer 1 can be set over the entire area of the Si wafer 1. Therefore, the local heater 15 carries out heating and melting processes several times while the movable wafer positioning base 19 is being shifted so as to allow the local heater 15 to shift along a crack 16 under the control of the personal computer 9 so that even in the case of a crack 16 having a comparatively large size that cannot be repaired by heating and melting processes of one time, the crack 16 can be repaired with high precision in the same manner as embodiment 7.

Moreover, in the present embodiment, for example, a crack 16 is repaired; however, the present embodiment is of course applied so as to repair a chipping 6.

### 10. Embodiment 10

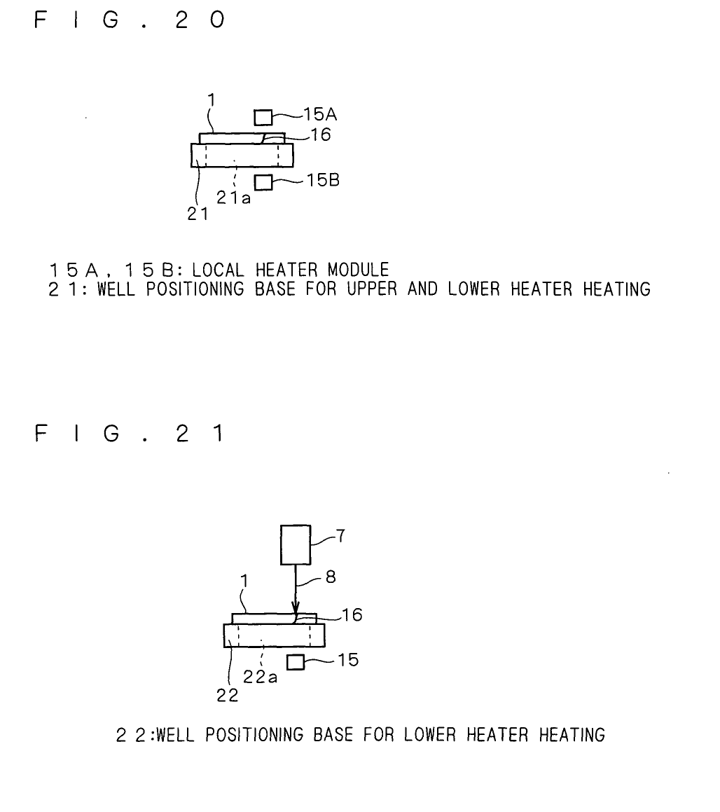

FIG. 19 is an explanatory diagram showing a peripheral area of a laser irradiation portion of a wafer crack prevention device according to embodiment 10 of the present invention. As shown in this figure, this device is provided with laser oscillators 7A, 7B in place of the laser oscillator 7, and wafer positioning base 20 for upper and lower laser irradiation on which a Si wafer 1 is mounted, in place of the wafer positioning base 4. Since an opening section 20a having a size slightly smaller than the Si wafer 1 is formed in the center of the wafer positioning base 20 for upper and lower laser irradiation so that the laser light beam can be applied from above the Si wafer 1 (surface) as well as from below the Si wafer 1 (rear surface).

Thus, a laser light beam 8A is applied to the Si wafer 1 by the laser oscillator 7A from above the Si wafer 1 and a laser light beam 8B is applied to the Si wafer 1 by the laser oscillator 7B from below the Si wafer 1 through the opening section 20a. Here, the other structure is the same as that of the entire structure of embodiment 1 shown in FIG. 1.

In the wafer crack prevention device of embodiment 10 having the above-mentioned structure, it becomes possible to melt the Si wafer 1 by applying the laser light beams from both of the surface and rear surface sides of the Si wafer 1, and consequently to melt the Si wafer 1; thus, as shown in FIG. 19, even when there is a crack 16 starting from the surface to reach the rear surface of the Si wafer 1, it becomes possible to carry out a repairing process with high precision.

Additionally, by allowing the laser oscillators 7A, 7B to have a movable structure like the movable laser oscillator 17 of embodiment 6 or allowing the wafer positioning base 20 for upper and lower laser irradiation to have a movable structure like that of embodiment 8, it of course becomes possible to repair a crack 16 having even a comparatively large size in the same manner as embodiment 6 and embodiment 8.

### 11. Embodiment 11

FIG. 20 is an explanatory diagram showing a peripheral area of a laser irradiation portion of a wafer crack prevention device according to embodiment 11 of the present invention. As shown in this figure, this device is provided with local heaters 15A, 15B in place of the laser oscillator 7, and upper and lower heater heating wafer positioning base 21 on which a Si wafer 1 is mounted, in place of the wafer positioning base 4. Since an opening section 20a having a size slightly smaller than the Si wafer 1 is formed in the center of the upper and lower heater heating wafer positioning base 21 so that the local heaters can apply heat from above the Si wafer 1 (surface) as well as from below the Si wafer 1 (rear surface).

Thus, the local heater 15A is allowed to heat and melt the Si wafer 1 from above the Si wafer 1 and the local heater 15B is allowed to heat and melt the Si wafer 1 from below the Si wafer 1 through the opening section 20a. Here, the other structure is the same as that of the entire structure of embodiment 1 shown in FIG. 1.

In the wafer crack prevention device of embodiment 11 having the above-mentioned structure, it becomes possible to melt the Si wafer 1 by applying heat by local heaters from both of the surface and rear surface sides of the Si wafer 1, and consequently to melt the Si wafer 1; thus, as shown in FIG. 20, even when there is a crack starting from the surface to reach the rear surface of the Si wafer 1, it becomes possible to carry out a repairing process with high precision.

Additionally, by allowing the local heaters 15A, 15B to have a movable structure like the movable local heater 18 of embodiment 7 or allowing the upper and lower heater heating wafer positioning base 21 to have a movable structure like that of embodiment 9, it of course becomes possible to repair a crack 16 having even a comparatively large size in the same manner as embodiment 7 and embodiment 9.

### 12. Embodiment 12

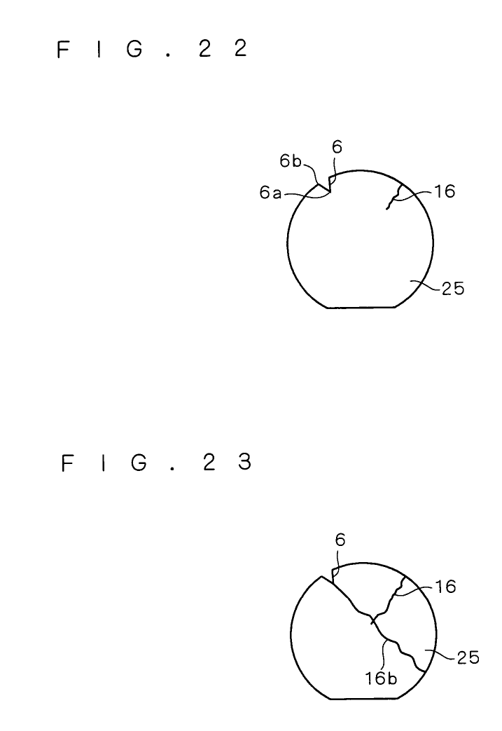

FIG. 21 is an explanatory diagram showing a peripheral area of a laser irradiation portion of a wafer crack prevention device according to embodiment 12 of the present invention. As shown in this figure, a local heater 15 is added to this device, and this device is provided with a lower heater heating wafer positioning base 22 on which a Si wafer 1 is mounted, in place of the wafer positioning base 4. Since an opening section 20a having a size slightly smaller than the Si wafer 1 is formed in the center of the lower heater heating wafer positioning base 22 so that the laser light beam can be applied from below the Si wafer 1 (rear surface).

Thus, a laser light beam 8 is applied to the Si wafer 1 by the laser oscillator 7 from above the Si wafer 1 and heating and melting processes are carried out by the local heater 15B from below the Si wafer 1 through the opening section 20a. Here, the other structure is the same as that of the entire structure of embodiment 1 shown in FIG. 1.

In the wafer crack prevention device of embodiment 12 having the above-mentioned structure, it becomes possible to apply a laser light beam 8A to the Si wafer 1 from below the Si wafer 1 by a laser oscillator 7A, while applying heat from below the Si wafer 1 by the local heater 15, so as to melt the Si wafer 1; thus, as shown in FIG. 21, even when there is a crack 16 starting from the surface to reach the rear surface of the Si wafer 1, it becomes possible to carry out a repairing process with high precision.

The application of either an arrangement in which the laser oscillator 7 is modified into the movable laser oscillator 17 as shown in embodiment 6, or an arrangement in which the local heater 15 is formed so as to have a movable arrangement like the movable local heater 18 of embodiment 7, or an arrangement in which the lower heater heating wafer positioning base 22 is formed so as to have a movable arrangement like the movable wafer positioning base 19 of embodiment 9, makes it possible to repair a crack 16 having a comparatively large shape, in the same manner as embodiments 6 to 9.

Since the present embodiment 12 has the laser oscillator 7 and the local heater 15 which serve as local melting means, it is possible to commonly achieve both of the characteristics of the laser oscillator 7 that are particularly effective for comparatively short chippings 6 and cracks 16 and the characteristics of the local heater 15 that are particularly effective for comparatively long chippings 6 and cracks 16.

While the invention has been shown and described in detail, the foregoing description is in all aspects illustrative and not restrictive. It is therefore understood that numerous other modifications and variations can be devised without departing from the scope of the invention.

1. A substrate defect repairing device comprising:
substrate mounting means (4, 19 to 22) for mounting a substrate to be processed;
defect detecting means (5, 9) for detecting the presence or absence of a defect in said substrate to be processed (1, 13, 14), and obtaining information for defect detection including a defect position, upon detection of the defect; and
defect repairing means (7, 7A, 7B, 9, 15, 15A, 15B, 17, 18) for repairing the defect by melting the defect portion and the peripheral area of said substrate to be processed on the basis of said information for defect detection.

2. The substrate defect repairing device according to claim 1, wherein
said defect repairing means includes:
local melting means (7, 7A, 7B, 15, 15A, 17, 18) for locally melting said substrate to be processed; and
melt-positioning means (4, 9, 19 to 22) for carrying out a positioning process so as to allow said local melting means to melt said defect portion and the peripheral area thereof on the basis of said information for defect detection.

3. The substrate defect repairing device according to claim 2, wherein
said local melting means includes a laser oscillator (7, 7A, 7B, 17) for locally applying a laser beam onto said substrate to be processed so as to melt the corresponding portion.

4. The substrate defect repairing device according to claim 2, wherein
said local melting means includes local heating means (15, 15A, 15B, 18) for locally heating said substrate to be processed.

5. The substrate defect repairing device according to claim 4, wherein
said local heating means includes a plurality of partial heating units which can be individually set in the lighting and lighting-out processes thereof.

6. The substrate defect repairing device according to claim 2, wherein
said local melting means includes fixed local melting means (7, 15) secured to a predetermined position,
said substrate mounting means includes movable substrate mounting means (19) capable of carrying out a shifting operation for shifting said substrate to be processed so as to change the portion to be melted by said local melting means, and
said melt-positioning means includes control means (9) controlling said shifting operation carried out by said substrate mounting means on the basis of said information defect detection.

7. The substrate defect repairing device according to claim 6, wherein
said substrate to be processed includes a disc-shaped substrate in its plane shape, and
the shifting operation by said movable substrate mounting means includes a rotative operation rotating said substrate to be processed at a substantially center position of said substrate to be processed as a center.

8. The substrate defect repairing device according to claim 6, wherein
the shifting operation by said movable substrate mounting means includes an operation shifting said substrate to be processed so that the meltable portion by said local melting means is changed within a predetermined shifting area in said substrate to be processed.

9. The substrate defect repairing device according to claim 2, wherein
said local melting means includes movable local melting means (17, 18) carrying out a shifting operation to shift itself so that the meltable portion by said local melting means is changed within a predetermined shifting area in said substrate to be processed, and
said melt-positioning means includes control means (9) controlling said shifting operation by said movable local melting means on the basis of said information for defect detection.

10. The substrate defect repairing device according to claim 2, wherein
said substrate to be processed has first and second main surfaces,
said substrate mounting means includes substrate mounting means (20 to 22) for two-directional melting for mounting said substrate to be processed in a manner so as to be subjected to a melting process from the respective sides of said first and second main surfaces, and
said local melting means includes first local melting means (7A, 15A) carrying out a melting process on said substrate to be processed from the first main surface side, and second local melting means (7B, 15B) carrying out a melting process on said substrate to be processed from the second main surface side.

11. The substrate defect repairing device according to claim 10, wherein
said first and second local melting means includes first and second laser oscillators (7A, 7B) locally applying laser beams on the first and second main surface sides of said substrate to be processed so as to carry out the melting processes.

12. The substrate defect repairing device according to claim 10, wherein
said first and second local melting means includes first and second local heating means (15A, 15B) locally heating said substrate to be processed from the first and second main surface sides, respectively.

13. The substrate defect repairing device according to claim 10, wherein
said first local melting means includes a laser oscillator (7) locally applying a laser beam to said substrate to be processed from the first main surface side so as to carry out a melting process, and
said second local melting means includes local heating means (15) locally heating said substrate to be processed from the second main surface side.

14. The substrate defect repairing device according to claim 1, further comprising:
a substrate housing unit (2) for housing a plurality of substrates; and
transporting means (3) capable of carrying out a first transporting process which takes one substrate out of said plurality of substrates in said substrate housing unit as said substrate to be processed and transports and mounts said substrate to be processed on said substrate mounting means, and a second transporting process which detaches said substrate to be processed from said substrate mounting means and transports and houses said substrate to be processed in said substrate housing unit.

15. The substrate defect repairing device according to claim 14, further comprising:
control means (9) for controlling said first and second transporting processes of said transporting means.

16. The substrate defect repairing device according to claim 1, wherein
said substrate to be processed includes a Si wafer (1), a GaAs substrate (13) or a glass substrate (14) for liquid crystal.

17. The substrate defect repairing device according to claim 1, wherein
said defect detecting means has a recording function of recording analysis information including at least information indicative of said defect position in said substrate to be processed.

18. The substrate defect repairing device according to claim 1, wherein
said defect includes a chipping (6) or a crack (16).
